(19) United States
(12) Patent Application Publication
(10) Pub. No.: US 2024/0113200 A1
(43) Pub. Date: Apr. 4, 2024

(54) INNER SPACER RELIABILITY MACRO DESIGN AND WELL CONTACT FORMATION

(71) Applicant: International Business Machines Corporation, Armonk, NY (US)

(72) Inventors: HUIMEI ZHOU, ALBANY, NY (US); MIAOMIAO WANG, ALBANY, NY (US); Julien Frougier, ALBANY, NY (US); Andrew M. Greene, Slingerlands, NY (US); Barry Paul Linder, Hastings-on-Hudson, NY (US); Kai Zhao, ALBANY, NY (US); Ruilong Xie, Niskayuna, NY (US); Tian Shen, San Jose, CA (US); Veeraraghavan S. Basker, Fremont, CA (US)

(21) Appl. No.: 17/960,116

(22) Filed: Oct. 4, 2022

(51) Int. Cl. H01L 29/66; H01L 21/768; H01L 21/8234; H01L 27/088; H01L 29/06; H01L 29/08

(52) U.S. Cl. CPC H01L 29/66553; H01L 21/76831; H01L 21/823412; H01L 21/823418; H01L 27/0886; H01L 29/0673; H01L 29/0847; H01L 29/66545

(57) ABSTRACT

An integrated circuit apparatus includes a substrate and a well contact that is disposed on the substrate. The well contact includes first and second source/drain structures that are disposed on the substrate; a metal vertical portion that contacts the substrate immediately between the first and second source/drain structures; inner spacers that electrically insulate the vertical portion from the adjacent source/drain structures; bottom dielectric isolation that electrically insulates the source/drain structures from the substrate; and a well portion that is embedded into the substrate in registry with the vertical portion. The well portion is doped differently than the substrate.

### BACKGROUND

The present invention relates to the electrical, electronic, and computer arts, and more specifically, to semiconductor devices and their fabrication.

When operating an integrated circuit, it is helpful to have the semiconductor substrate of the circuit reverse-biased as a diode, so that the substrate will not leak current between transistors of the circuit. Accordingly, different substrate dopings are used, depending on what type of transistor overlies the substrate, i.e., a p-doped substrate for an n−type field effect transistor (nFET) or an n-doped substrate for a p−type field effect transistor (pFET). Components known as “well contacts” are used to reverse-bias or ground the substrate. Well contacts include a “well” region of the substrate that is doped opposite to the adjoining bulk region of the substrate, e.g., a “p-well” for an n-doped bulk of the substrate, and vice-versa. Well contacts also include a metal portion (essentially a via) that penetrates the circuit stack from the interconnect layer down to the well. Typically, the metal portion of the well contact is formed in a separate part of the integrated circuit from the gates and source/drain structures. Meanwhile, inner spacer breakdown is a component of Vₘₐₓ evaluation for circuit reliability.

### SUMMARY

Principles of the invention provide techniques for inner spacer reliability macro design and well contact formation.

In one aspect, an exemplary integrated circuit apparatus includes a substrate and a well contact that is disposed on the substrate. The well contact includes first and second source/drain structures that are disposed on the substrate; a metal vertical portion that contacts the substrate immediately between the first and second source/drain structures; inner spacers that electrically insulate the vertical portion from the adjacent source/drain structures; bottom dielectric isolation that electrically insulates the source/drain structures from the substrate; and a well portion that is embedded into the substrate in registry with the vertical portion. The well portion is doped differently than the substrate.

According to another aspect, an exemplary method includes, forming a precursor. The precursor includes a dummy gate, first and second source/drain structures at either side of the dummy gate, and first and second sacrificial nanosheets, between the source/drain structures below the dummy gate. The method also includes, forming a first trench by removing the dummy gate; forming a liner at sides of the first trench; etching a second trench through the first and second sacrificial nanosheets; forming first gaps at the sides of the second trench by etching the first sacrificial nanosheets; and forming second gaps at the sides of the second trench by releasing the second sacrificial nanosheets.

According to another aspect, an exemplary integrated circuit apparatus includes a substrate; an array of transistors that are disposed on the substrate; and a well contact that is formed among the array of transistors on the substrate.

In view of the foregoing, techniques of the present invention can provide substantial beneficial technical effects. For example, in one or more embodiments, combining fin cut and gate cut design and process advantageously enables:

In-process evaluation of inner spacer reliability and Vₘₐₓ.

Well contact to whole circuit without any additional mask.

Some embodiments may not have these potential advantages and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 depicts, in a schematic taken at view line A of FIG. 2, a well contact according to exemplary embodiments.

FIG. 2 depicts, in a schematic, a plan view of the well contact that is shown in FIG. 1.

FIG. 3 through FIG. 17 depict, in schematics, precursor structures to the well contact that is shown in FIG. 1.

FIG. 18 depicts, in a schematic, another well contact according to exemplary embodiments.

FIG. 19 and FIG. 20 depict, in schematics, precursors to the well contact that is shown in FIG. 18.

FIG. 21 depicts, in a flowchart, steps of a method for making the well contact that is shown in FIG. 1.

### DETAILED DESCRIPTION

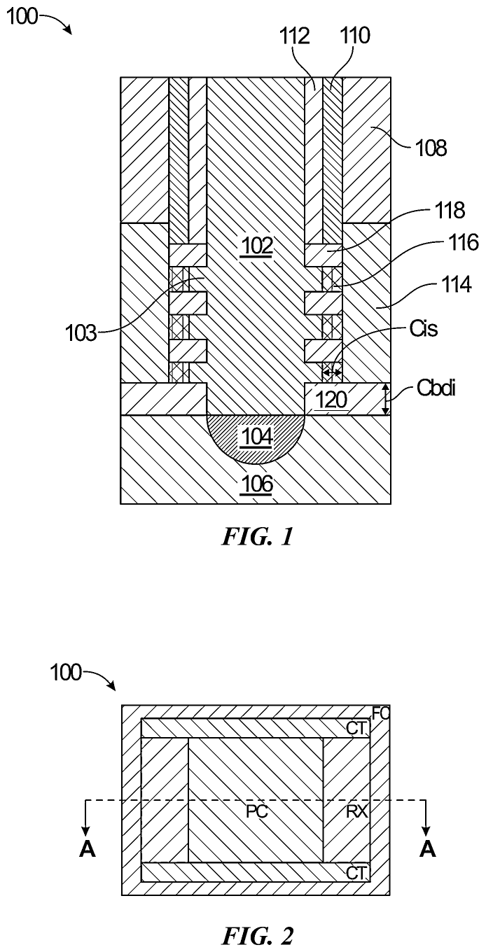

FIG. 1 depicts, in a schematic taken at view line A of FIG. 2, a well contact 100 according to exemplary embodiments. The well contact 100 includes a central vertical shaft 102, lugs 103 that protrude horizontally from the shaft, and a well portion 104 that is embedded into a substrate 106. The well portion 104 is doped differently than the substrate 106, e.g., it can be doped of an opposite type (n−type vs p−type) or it can be doped with a higher concentration of the same type (n+type vs n−type or p+type vs p−type). In this context, “+type” means the same type of dopant, at a higher concentration. As used herein, the term “conductivity type” denotes a dopant region being p−type or n−type. As further used herein, “p−type” refers to the addition of impurities to an intrinsic semiconductor that creates deficiencies of valence electrons. In a silicon-containing substrate, examples of p−type dopants, i.e., impurities include but are not limited to: boron, aluminum, gallium and indium. As used herein, “n−type” refers to the addition of impurities that contribute free electrons to an intrinsic semiconductor. Examples of n−type dopants, i.e., impurities in a silicon-containing substrate include but are not limited to: antimony, arsenic and phosphorous.

The vertical shaft 102 is insulated from source/drain contacts 108 by a first spacer 110 and a liner 112. The vertical shaft 102 also is insulated from source/drain structures 114 by inner spacers 116 and dielectric plugs 118. The substrate 106 is insulated from the source/drain structures 114 by a bottom dielectric isolation 120. A horizontal thickness Cis of the inner spacers 116 is less than a vertical thickness Cbdi of the bottom dielectric isolation 120.

Advantageously, the well contact 100 is disposed immediately between the source/drain structures 114, where a gate stack might otherwise be located. This arrangement of the well contact enables it to easily be integrated into a circuit layout, without requiring provision of a special location and configuration for the well contact. Additionally, positioning the well contact in close proximity to source/drain structures advantageously enhances the effectiveness of the well contact for reverse-biasing or grounding the substrate near the working transistors.

FIG. 2 depicts, in a schematic, a plan view of the well contact 100 that is shown in FIG. 1, which is taken at view line A of FIG. 2. In FIG. 2, FC denotes fin cut. RX denotes an active region. CT is a “gate cut” region, which conventionally separates adjacent transistors or, in embodiments of the invention, separates the well contact 100 from adjacent transistors. PC denotes a “gate” region, which in embodiments of the invention is filled not by a traditional gate stack but rather by the well contact 100.

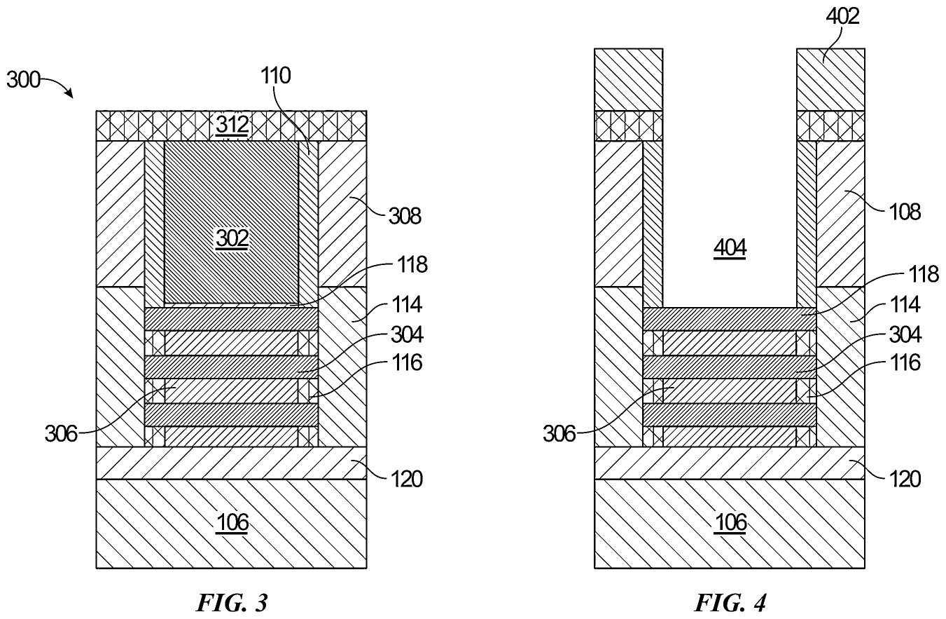

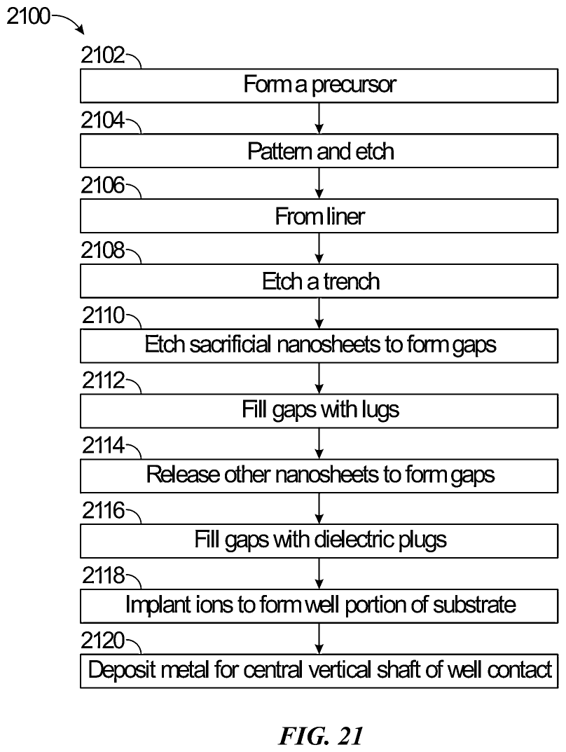

FIG. 3 through FIG. 17 depict, in schematics, precursor structures to the well contact that is shown in FIG. 1. FIG. 3 through FIG. 17 are further discussed with reference to steps of a method 2100, which is shown in a flow chart in FIG. 21.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures.

Various structures that are described herein, e.g., source/drain structures, may be epitaxially grown. “Epitaxy” or “epitaxial growth,” as used herein, refers to a process by which a layer of single-crystal or large-grain polycrystalline material is formed on an existing material with similar crystalline properties. One feature of epitaxy is that this process causes the crystallographic structure of the existing substrate or seed layer (including any defects therein) to be reproduced in the epitaxially grown material. Epitaxial growth can include heteroepitaxy (i.e., growing a material with a different composition from its underlying layer) or homoepitaxy (i.e., growing a material which includes the same composition as its underlying layer). Heteroepitaxy can introduce strain in the epitaxially grown material, as its crystal structure may be distorted to match that of the underlying layer. In certain applications, such strain may be desirable. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material may have the same crystalline characteristics as the deposition surface on which it may be formed. For example, an epitaxial semiconductor material deposited on a {100} crystal surface may take on a {100} orientation. In some embodiments, epitaxial growth and/or deposition processes may be selective to forming on semiconductor surfaces, and may not deposit material on dielectric surfaces, such as silicon dioxide or silicon nitride surfaces.

A number of different precursors may be used for the epitaxial deposition of the in situ doped semiconductor material. In some embodiments, the gas source for the deposition of an epitaxially formed in situ doped semiconductor material may include silicon (Si) deposited from silane, disilane, trisilane, tetrasilane, hexachlorodisilane, tetrachlorosilane, dichlorosilane, trichlorosilane, disilane and combinations thereof. In other examples, when the in situ doped semiconductor material includes germanium, a germanium gas source may be selected from the group consisting of germane, digermane, halogermane, dichlorogermane, trichlorogermane, tetrachlorogermane and combinations thereof. Examples of other epitaxial growth processes that can be employed in growing semiconductor layers described herein include rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE).

By “in-situ” it is meant that the dopant that dictates the conductivity type of doped layer is introduced during the process step, for example epitaxial deposition, that forms the doped layer. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

Referring to the method 2100 of FIG. 21 as well as FIG. 3, at 2102, form a precursor 300 that includes a dummy gate 302, semiconductor nanosheets 304, and sacrificial semiconductor nanosheets 306. The source/drain structures 114 flank the nanosheets 304, 306 with intervening inner spacers 116. An interlayer dielectric 308 flanks the first spacer 110 alongside the dummy gate 302. Bottom dielectric isolation 120 insulates the nanosheets and the source/drain structures from the substrate 106. A hard mask 312 (e.g., silicon nitride) covers the precursor 300.

Conventionally, this precursor 300 would be processed to form a transistor in which the nanosheets 304 became channel structures. However, according to exemplary embodiments, the nanosheets 304 instead will be sacrificed in forming the well contact 100, as will further be discussed with reference to subsequent drawing views and steps of the method 2100.

Referring now to FIG. 4 and FIG. 21, at 2104, deposit and pattern an optical planarization layer 402 and etch a trench 404 that removes the dummy gate 302 to form a structure as shown.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

As an exemplary subtractive process, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

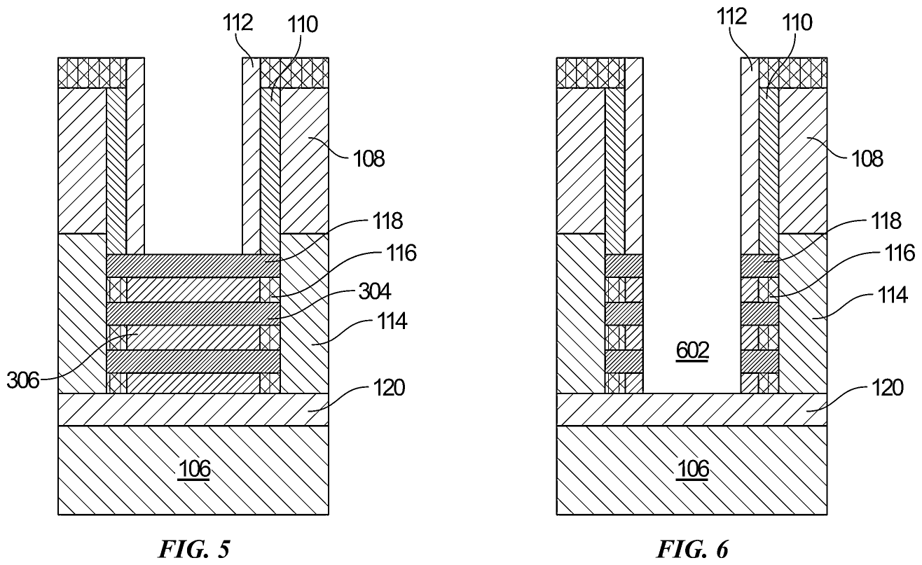

At 2106, as shown in FIG. 5 and FIG. 21, form the liner 112 that lines sidewalls of the trench 404.

Referring to FIG. 6 and FIG. 21, at 2108, etch a trench 602 that removes central portions of the nanosheets 304, 306.

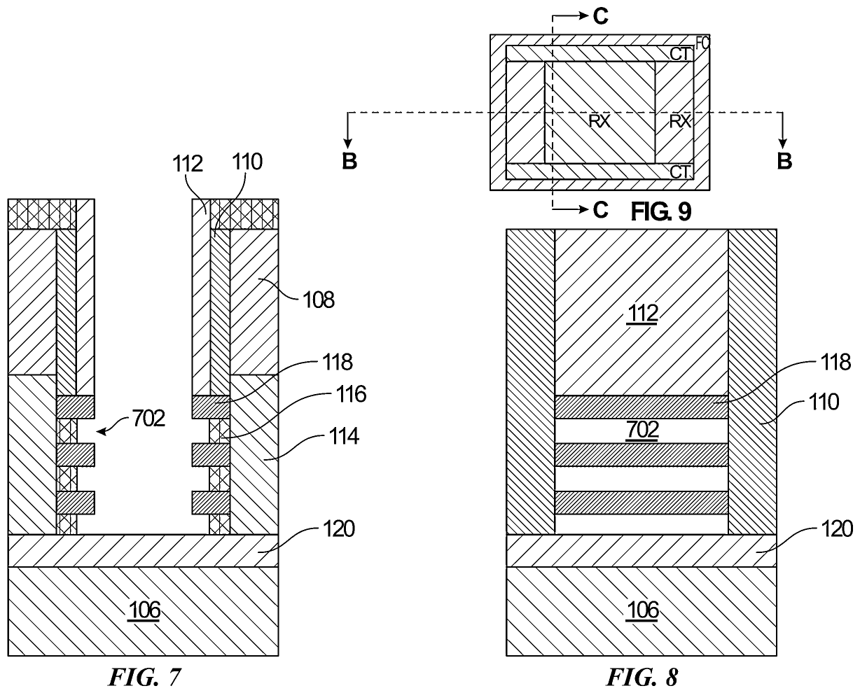

At 2110, as shown in FIG. 7 and FIG. 21, etch the sacrificial nanosheets 306 (numbered in FIG. 5) selective to the nanosheets 304 (numbered in FIG. 5). This step forms gaps 702 that reveal the inner spacers 116 (numbered in FIG. 1) to the trench 602 (numbered in FIG. 6). The gaps 702 also can be seen in FIG. 8. FIG. 7 is taken at view line B of FIG. 9, while FIG. 8 is taken at view line C.

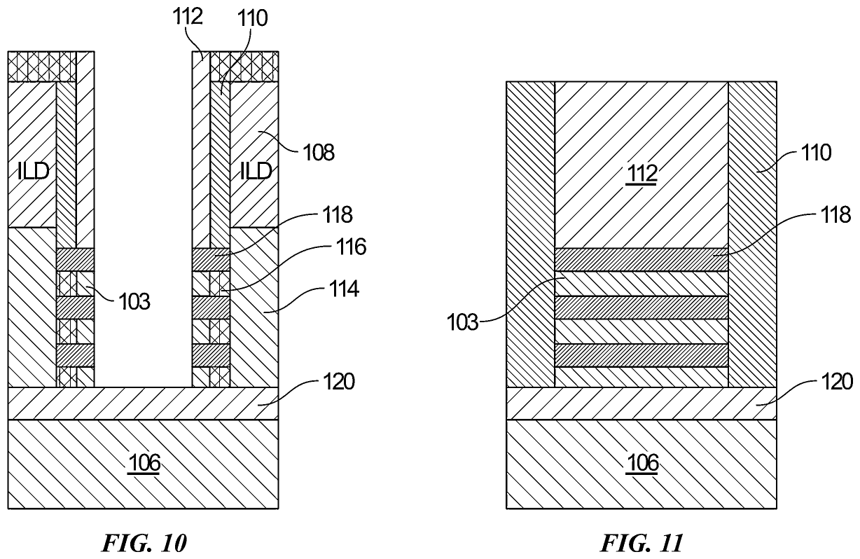

Referring to FIG. 10 and FIG. 11, which correspond respectively to view lines B and C of FIG. 9, at 2112, first deposit and then etch a contact material that fills the gaps 702 with the lugs 103. Contact material may, for example, include tantalum (Ta), aluminum (Al), platinum (Pt), gold (Au), titanium (Ti), palladium (Pd) or any combination thereof. The contact material may be deposited by, for example, chemical vapor deposition (CVD), Plasma-enhanced chemical vapor deposition (PECVD), PVD (Physical Vapor Deposition), plating, thermal or e-beam evaporation, or sputtering.

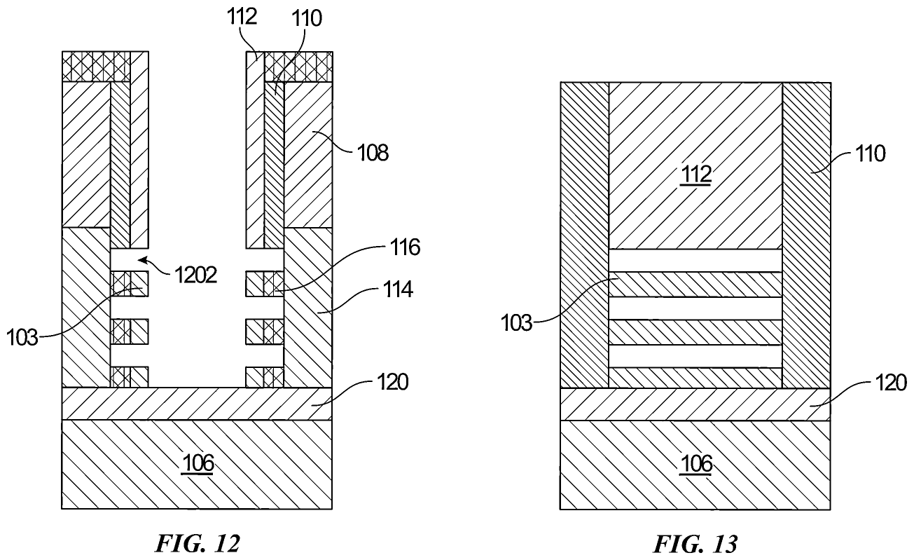

At 2114, as shown in FIG. 12 and FIG. 13 (corresponding to view lines B and C, respectively), release the nanosheets 304 to form gaps 1202 that reveal the source/drain structures 114 to the trench 602.

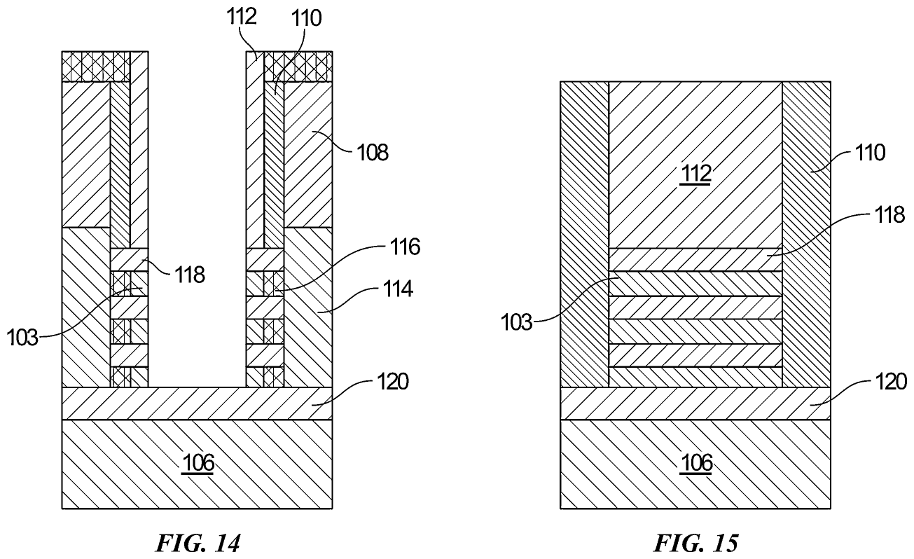

Referring to FIG. 14 and FIG. 15, at 2116, fill the gaps 1202 (shown in FIG. 12 and FIG. 13) by first depositing and then etching a dielectric material that forms the dielectric plugs 118.

In step 2112 and 2116, the etching may be anisotropic (e.g., reactive ion etching or RIE), or it may be isotropic, depending on whether the gaps 702, 1202 are sufficiently narrow in height so as to “pinch off” the material that is deposited into them.

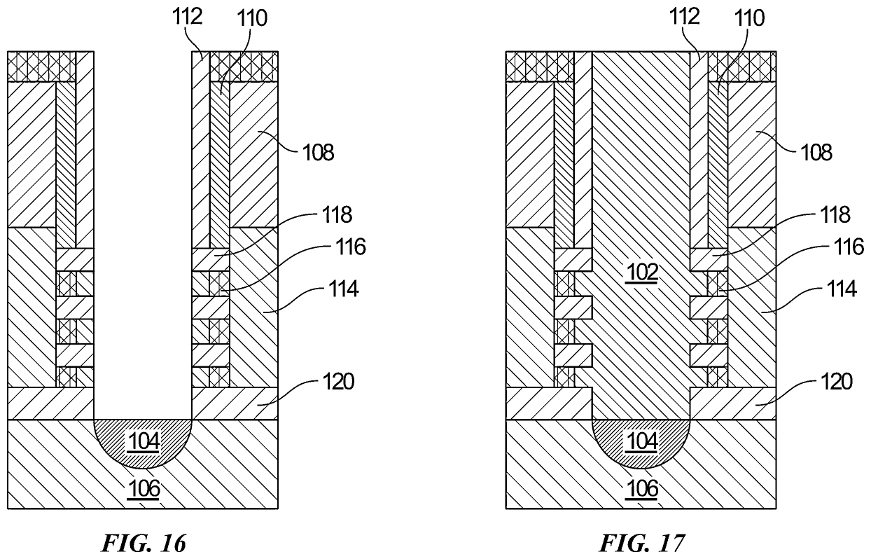

Referring to FIG. 16, at 2118, implant ions into the substrate 106 to form the well portion 104.

At 2120, as shown in FIG. 17, deposit additional metal to form the vertical shaft 102.

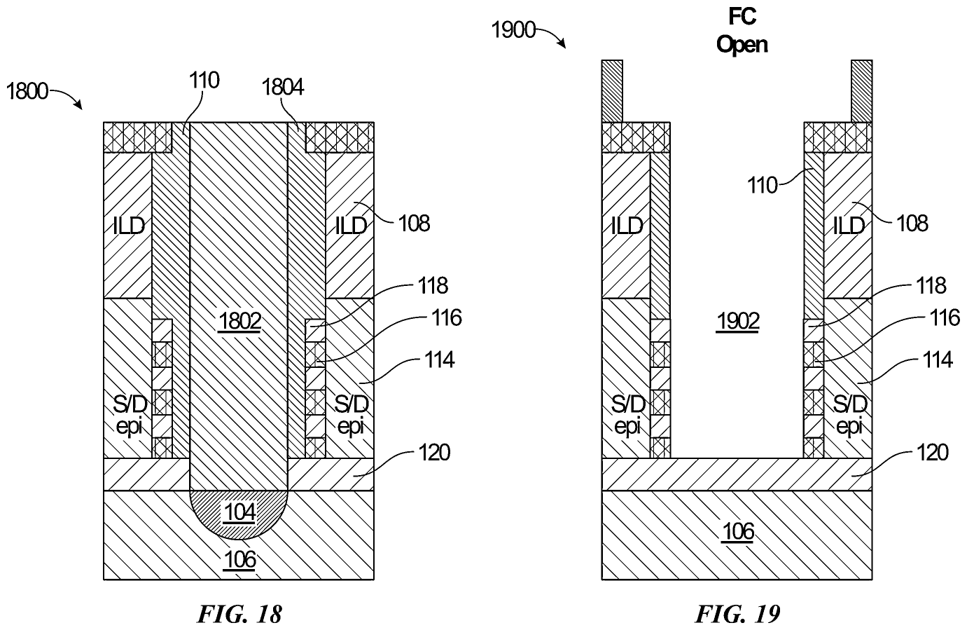

FIG. 18 depicts, in a schematic, another well contact 1800 according to exemplary embodiments. The well contact 1800 includes a central vertical shaft 1802, without any lugs. It has, in addition to the spacer 110, a doubled spacer 1804.

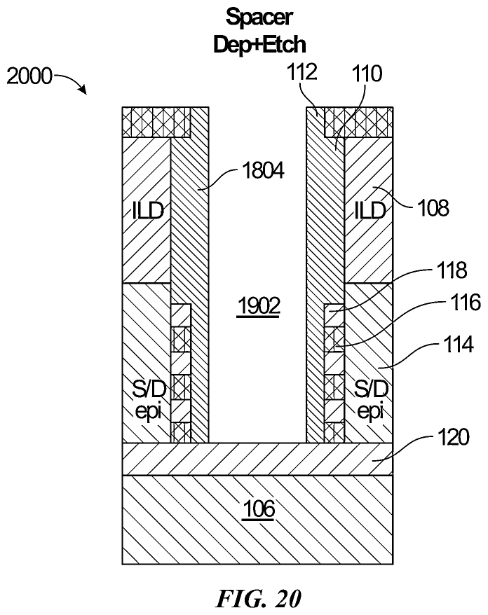

FIG. 19 and FIG. 20 depict, in schematics, precursors to the well contact that is shown in FIG. 18. Precursor 1900 (in FIG. 19) has been etched to form a trench 1902, in which the spacer 110 has been formed. Then in FIG. 20, the doubled spacer 1804 is deposited to form precursor 2000. Then, to produce the well contact 1800, the precursor 2000 of FIG. 20 is etched to open the bottom dielectric isolation 120, ions are implanted into the substrate 106 to form the well region 104, and the central vertical shaft 1802 is formed.

FIG. 21 depicts, in a flowchart, steps of a method 2100 for making the well contact 100 that is shown in FIG. 1. The steps of the method 2100 have been previously discussed with reference to FIG. 3 through FIG. 17. To recapitulate, the method 2100 includes: at 2102, form a precursor. At 2104, pattern and etch the precursor. At 2106, form a liner. At 2108, etch a trench. At 2110, etch sacrificial nanosheets to form gaps at the sides of a trench. At 2112, fill the gaps with metal lugs. At 2114, release other nanosheets to form gaps at the sides of the trench. At 2116, fill the gaps with dielectric plugs. At 2118, implant ions into the substrate to form a well portion of the substrate at the bottom of the trench. At 2120, deposit metal into the trench to form a central vertical shaft of the well contact.

In one or more embodiments, the narrowness of the inner spacers relative to the bottom dielectric isolation advantageously results in the structure 100 being useful for testing inner spacer breakdown properties (e.g., voltage, current). Thus, in certain embodiments, an additional step is to apply a breakdown voltage to the well contact 100 during a post-fabrication circuit test.

Given the discussion thus far, it will be appreciated that in general terms, an exemplary integrated circuit apparatus includes a substrate 106 and a well contact 100 that is disposed on the substrate. The well contact includes first and second source/drain structures 114 that are disposed on the substrate; a metal vertical portion 102 that contacts the substrate immediately between the first and second source/drain structures; inner spacers 116 that electrically insulate the vertical portion from the adjacent source/drain structures; bottom dielectric isolation 120 that electrically insulates the source/drain structures from the substrate; and a well portion 104 that is embedded into the substrate in registry with the vertical portion. The well portion is doped differently than the substrate.

In one or more embodiments, a vertical thickness of the bottom dielectric isolation is greater than a horizontal thickness of the inner spacers.

In one or more embodiments, the vertical portion of the well contact comprises: a central vertical shaft 102 and lugs 103 that protrude horizontally from the vertical shaft. In one or more embodiments, the lugs contact the inner spacers. In one or more embodiments, the lugs and the shaft are the same material. In one or more embodiments, the well contact also includes dielectric layers 118 that are interleaved with the lugs and the inner spacers.

In one or more embodiments, the well portion includes one of an n−type dopant and a p−type dopant, and the substrate includes the other of an n−type dopant and a p−type dopant. In one or more embodiments, the substrate includes a first concentration of a first dopant and the well portion includes a second concentration of a dopant of the same type as the first dopant, with the second concentration higher than the first concentration.

According to another aspect, an exemplary method 2100 includes, at 2102, forming a precursor 300. The precursor includes a dummy gate 302, first and second source/drain structures 114 at either side of the dummy gate, and first and second sacrificial nanosheets 304, 306 between the source/drain structures below the dummy gate. The method 2100 also includes, at 2104, forming a first trench 404 by removing the dummy gate; at 2106, forming a liner 112 at sides of the first trench; at 2108, etching a second trench 602 through the first and second sacrificial nanosheets; at 2110, forming first gaps 702 at the sides of the second trench by etching the first sacrificial nanosheets; and at 2114, forming second gaps 1202 at the sides of the second trench by releasing the second sacrificial nanosheets.

In one or more embodiments, the method also includes, at 2112, filling the first gaps with metal lugs 103 before releasing the second nanosheets.

In one or more embodiments, the method also includes, at 2116, filling the second gaps with dielectric plugs 118.

In one or more embodiments, the method also includes, at 2118, forming a well portion 104 of the substrate 106 by implanting ions into the substrate at the bottom of the second trench 602.

In one or more embodiments, the substrate is doped one of n−type and p−type, and the method also includes, at 2118, doping the well portion the other of n−type and p−type. the method also includes, at 2118, doping the well portion to a higher concentration the same type as the substrate.

In one or more embodiments the method also includes, at 2120, forming a central vertical shaft of the well contact by depositing metal into the second trench after filling the second gaps with the dielectric plugs.

According to another aspect, an exemplary integrated circuit apparatus includes a substrate; an array of transistors that are disposed on the substrate; and a well contact that is formed among the array of transistors on the substrate.

In one or more embodiments, the well contact 100 includes first and second source/drain structures 114 that are disposed on the substrate; a metal vertical portion 102 that contacts the substrate immediately between the first and second source/drain structures; inner spacers 116 that electrically insulate the vertical portion from the adjacent source/drain structures; bottom dielectric isolation 120 that electrically insulates the source/drain structures from the substrate; and a well portion 104 that is embedded into the substrate in registry with the vertical portion. The well portion is doped differently than the substrate.

In one or more embodiments, a vertical thickness of the bottom dielectric isolation is greater than a horizontal thickness of the inner spacers.

In one or more embodiments, the vertical portion of the well contact includes a central vertical shaft; and lugs that protrude horizontally from the vertical shaft.

In one or more embodiments, the lugs and the shaft are the same material.

In one or more embodiments, the well portion includes one of an n−type dopant and a p−type dopant, and the substrate includes the other of an n−type dopant and a p−type dopant. In one or more embodiments, the substrate includes a first concentration of a first dopant and the well portion includes a second concentration of a dopant of the same type as the first dopant, with the second concentration higher than the first concentration.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An integrated circuit apparatus that comprises:
a substrate; and
a well contact that is disposed on the substrate, wherein the well contact comprises:
first and second source/drain structures that are disposed on the substrate;
a metal vertical portion that contacts the substrate immediately between the first and second source/drain structures;
inner spacers that electrically insulate the vertical portion from the adjacent source/drain structures;
bottom dielectric isolation that electrically insulates the source/drain structures from the substrate; and
a well portion that is embedded into the substrate in registry with the vertical portion, wherein the well portion is doped differently than the substrate.

2. The apparatus of claim 1, wherein a vertical thickness of the bottom dielectric isolation is greater than a horizontal thickness of the inner spacers.

3. The apparatus of claim 1, wherein the vertical portion of the well contact comprises:
a central vertical shaft; and lugs that protrude horizontally from the vertical shaft.

4. The apparatus of claim 3, wherein the lugs contact the inner spacers.

5. The apparatus of claim 3, wherein the lugs and the shaft are the same material.

6. The apparatus of claim 3, further comprising dielectric layers that are interleaved with the lugs and the inner spacers.

7. The apparatus of claim 1, wherein the substrate includes one of an n−type dopant and a p−type dopant and the well portion includes the other of an n−type dopant and a p−type dopant.

8. The apparatus of claim 1, wherein the substrate includes a first concentration of a first dopant and the well portion includes a second concentration of a dopant of the same type as the first dopant, wherein the second concentration is higher than the first concentration.

9. A method comprising:
forming a precursor that comprises: a dummy gate, first and second source/drain structures at either side of the dummy gate, and first and second sacrificial nanosheets between the source/drain structures below the dummy gate;
forming a first trench by removing the dummy gate;
forming a liner at sides of the first trench;
etching a second trench through the first and second sacrificial nanosheets;
forming first gaps at the sides of the second trench by etching the first sacrificial nanosheets; and
forming second gaps at the sides of the second trench by releasing the second sacrificial nanosheets.

10. The method of claim 9, further comprising:
filling the first gaps with metal lugs before releasing the second nanosheets.

11. The method of claim 9, further comprising:
filling the second gaps with dielectric plugs.

12. The method of claim 9, further comprising:
forming a well portion of the substrate by implanting ions into the substrate at the bottom of the second trench.

13. The method of claim 12, wherein the substrate is doped one of n−type and p−type, further comprising doping the well portion the other of n−type and p−type.

14. The apparatus of claim 12, further comprising doping the well portion to a higher concentration the same type as the substrate.

15. The method of claim 9, further comprising:
forming a central vertical shaft of the well contact by depositing metal into the second trench after filling the second gaps with the dielectric plugs.

16. An integrated circuit apparatus that comprises:
a substrate;
an array of transistors on the substrate; and
a well contact that is formed among the array of transistors on the substrate.

17. The apparatus of claim 16, wherein the well contact comprises:
first and second source/drain structures that are disposed on the substrate;
a metal vertical portion that contacts the substrate immediately between the first and second source/drain structures;
inner spacers that electrically insulate the vertical portion from the adjacent source/drain structures;
bottom dielectric isolation that electrically insulates the source/drain structures from the substrate; and
a well portion that is embedded into the substrate in registry with the vertical portion, wherein the well portion is doped differently than the substrate.

18. The apparatus of claim 17, wherein a vertical thickness of the bottom dielectric isolation is greater than a horizontal thickness of the inner spacers.

19. The apparatus of claim 16, wherein the substrate includes one of an n−type dopant and a p−type dopant and the well portion includes the other of an n−type dopant and a p−type dopant.

20. The apparatus of claim 16, wherein the substrate includes a first concentration of a first dopant and the well portion includes a second concentration of a dopant of the same type as the first dopant, wherein the second concentration is higher than the first concentration.
